(19) United States
(12) Patent Application Publication
(10) Pub. No.: US 2013/0342238 A1
(43) Pub. Date: Dec. 26, 2013

(54) SEMICONDUCTOR DEVICE INCLUDING TRI-STATE CIRCUIT

(71) Applicant: Elpida Memory, Inc., Tokyo (JP)

(72) Inventor: Tetsuya ARAI, Tokyo (JP)

(73) Assignee: ELPIDA MEMORY, INC., Tokyo (JP)

(21) Appl. No.: 13/708,488

(22) Filed: Dec. 7, 2012

(30) Foreign Application Priority Data
Dec. 15, 2011 (JP) 2011-274865

(51) Int. Cl. H03K 19/094

(52) U.S. Cl. CPC H03K 19/094
USPC 326/57

(57) ABSTRACT

Disclosed herein is a device that includes first and second logic circuits driving first and second output nodes, respectively. The first logic circuit includes first and second transistors that are coupled in series between the first output node and a power line, in which the first transistor is controlled to change between a conductive state and a non-conductive state and the second transistor is controlled to keep a conductive state. The second gate circuit includes third and fourth transistors that are coupled in series between the second output node and the power line, in which each of the third and fourth transistors is controlled to change between a conductive state and a non-conductive state.

### BACKGROUND OF THE INVENTION

1. Field of the Invention

This application is based upon and claims the benefit of the priority of Japanese patent application No. 2011-274865, filed on Dec. 15, 2011, the disclosure of which is incorporated herein in its entirety by reference thereto. This invention relates to a device (semiconductor device) including a three-state buffer.

2. Description of Related Art

A three-state buffer, also termed a tri-state buffer, has a control terminal to receive a control signal that controls output enable/output disable of the buffer. An output of the three-state buffer is set to a low impedance or a high impedance depending on the value of the control signal. When the output is enabled, the output of the three-state buffer is High or Low voltage, depending on an input signal, whereas, when the output is disabled, the output of the three-state buffer is in a high-impedance state. In this manner, the output of the three-state buffer assumes three states. The three-state buffer is used e.g., in an output buffer of an input/output circuit wherein an output of the output buffer is set in a high-impedance state when a signal is received by the input/output circuit. Alternatively, the three-state buffer may be used as a driving buffer circuit connected to such as a common bus. For example, a control terminal OE of one of a plurality of driving buffers (three-state buffers) is activated to set one driving buffer to an output enable state, whilst the control terminals of the remaining driving buffers are deactivated, with the outputs of these remaining driving buffers being set in the high-impedance states. Still alternatively, the three-state buffer may be used in such a system in which outputs of a plurality of three state buffers with different current driving capabilities are connected in common to a single output terminal, and the three state buffers to be set to the output enable are selected to variably adjust current driving capability.

Japanese Patent Kokai Publication No. JP-S61-025326A discloses a three state buffer, in which a PMOS (P-channel MOS) transistor of a CMOS (Complementary MOS) buffer has a gate connected to an output of a NAND circuit and an NMOS (N-channel MOS) transistor of the CMOS buffer has a gate connected to an output of a NOR circuit. The CMOS buffer is composed by the PMOS transistor and an NMOS transistor connected between a power supply terminal and a ground terminal. The NAND circuit receives an output control signal and a signal output from a first inverter that receives and outputs an inverted version of the data input signal. The NOR circuit receives an inverted signal of the data input signal output from the first inverter and a signal output from a second inverter that inverts the output control signal. When the output control signal is in an activated state (High) and the data input signal is High, the output of the NAND circuit is High and the output of the NOR circuit is also High. The PMOS transistor is rendered non-conductive (turned off), while the NMOS transistor is rendered conductive (turned on), and hence the data output terminal goes Low. When the data input signal is Low, the output of the NAND circuit is Low, and the output of the NOR circuit also being Low. Hence, the PMOS transistor is rendered conductive (turned on), while the NMOS transistor is rendered non-conductive (turned off), so that the data output terminal goes High. When the output control signal is in a deactivated state (Low), the output of the NAND circuit is High, and the output of the NOR circuit is Low, irrespective of the value of the data input signal, so that both the NMOS transistor and the PMOS transistor are rendered non-conductive (turned off). In this configuration, the circuit configuration of a signal path connecting to the gate terminal of the PMOS transistor (logic gate configuration) differs from that of the signal path connecting to the gate terminal of the NMOS transistor.

Japanese Patent Kokai Publication No.JP-H08-116248A discloses a three state buffer in which a PMOS transistor of a CMOS transistor output circuit has a gate connected to an output of a NAND circuit and an NMOS transistor of the CMOS transistor has a gate connected to an output of an AND circuit. The NAND circuit receives an inner output signal and an output control signal. The AND circuit receives an output of an inverter that inverts the inner output signal and the output control signal. In the subject three state buffer, the circuit configuration of a signal path connected to the gate terminal of the PMOS transistor, differs from that of a signal path connected to the gate terminal of the NMOS transistor.

Japanese Patent Kokai Publication No. JP2001-24496A, which corresponds to U.S. Pat. No. 6,236,234B1 discloses an open-drain three state buffer in which a PMOS transistor of a CMOS transistor output circuit has a gate connected to an output of a NAND circuit and an NMOS transistor of the CMOS transistor output circuit has a gate connected to an output of an AND circuit. The NAND circuit receives an inner output signal and an output control signal. The AND circuit receives an output from an inverter that outputs an inverted version of the inner output signal and the output control signal. There is also provided an NMOS transistor having a gate connected to a second power supply between a connection node of the PMOS transistor and the NMOS transistor of the CMOS output circuit and an external output terminal. In this three state buffer, the circuit configuration of a signal path connecting to the gate terminal of the PMOS transistor differs from that of a signal path connecting to the gate terminal of the NMOS transistor.

Japanese Patent Kokai Publication No. JP-H08-8714A discloses a buffer circuit in which a PMOS transistor of a CMOS inverter has a gate connected to an output of two stages of inverters that receives an output of a first NAND circuit that receives a control signal and an input signal and an NMOS transistor of the CMOS inverter has a gate connected to an output of a first inverter that inverts an output of a second NAND circuit that receives the control signal and a signal from a second inverter that receives and inverts the input signal. In the this buffer circuit, a signal path connecting to the gate terminal of the PMOS transistor and that connecting to the gate terminal of the NMOS transistor are both composed by the NAND circuits and the inverters and have the logic matched to each other. However, they differ in the connection configuration and hence differ in signal propagation characteristics from the inner output terminals.

Japanese Patent Kokai Publication No. JP-H11-274906A shows a buffer circuit in which a PMOS transistor of a CMOS inverter has a gated connected to an output of a first inverter Iv1 that inverts an output of a first NOR circuit that receives a control signal HiZ and an input signal DOB and an NMOS transistor of the CMOS inverter has a gate connected to an output of a second NOR circuit that receives the control signal HiZ and an output of a second inverter Iv2 that inverts the input signal DOB. In the subject buffer circuit, a signal path connecting to the gate terminal of the PMOS transistor and that connecting to the gate terminal of the NMOS transistor are both composed by the NOR circuits and the inverters and have the logic matched to each other. However, they differ in the connection configuration and hence differ in signal propagation characteristics from the inner output terminals.

In the three state buffers, disclosed in the above mentioned Patent Literatures, the circuit configurations as well as the connection configurations of the circuits connecting respectively to gates of PMOS and NMOS transistors of the CMOS buffer differ from each other. Thus, the inventor has discovered that there appear difference in signal propagation characteristics between the signal path connecting to the gate of the PMOS transistor and that connecting to the gate of the NMOS transistor, for example, thus producing a difference in skew there-between. In addition, there may also be produced the difference in jitter there-between due to variations in the power supply voltages, ambient temperatures or fabrication processes.

### SUMMARY

In one aspect of this disclosure, there is provided a device that includes a first power line supplied with a first voltage as a first logic level, a second power line supplied with a second voltage as a second logic level, first and second input nodes supplied with first and second signals, respectively, first and second output nodes, and first and second gate circuits. The first gate circuit is coupled to the first and second power lines, the first and second input nodes and the first output node and configured to respond to an inactive level of the first signal to bring the first output node to a first selected one of the first and second logic levels irrespective of a level of the second signal and respond to an active level of the first signal to drive the first output node to a logic level controlled by the level of the second signal. The first logic circuit includes first and second transistors that are coupled in series between the first output node and the first power line, in which the first transistor makes response to at least one of the first and second signals to change between a conductive state and a non-conductive state, and the second transistor makes no response to any one of the first and second signals to keep a conductive state. On the other hand, the second gate circuit is coupled to the first and second power lines, the first and second input nodes and the second output node and configured to respond to the inactive level of the first signal to bring the second output node to a second selected one of the first and second logic levels irrespective of the level of the second signal and respond to the active level of the first signal to drive the second output node to a logic level that is equal to the logic level of the first output node. The second logic circuit includes third and fourth transistors that are coupled in series between the second output node and the first power line, in which each of the third and fourth transistors making response to at least one of the first and second signals to change between a conductive state and a non-conductive state.

### BRIEF DESCRIPTION OF THE DRAWINGS

FIG. 1 is a circuit diagram illustrating a circuit configuration of a first embodiment of the present invention.

FIG. 2 is a circuit diagram illustrating a circuit configuration of the first embodiment of the present invention on the transistor level.

FIG. 3 is a circuit diagram illustrating a circuit configuration of a second embodiment of the present invention.

FIG. 4 is a circuit diagram illustrating a circuit configuration of the second embodiment of the present invention on the transistor level.

FIG. 5 is a circuit diagram illustrating a circuit configuration of a third embodiment of the present invention.

FIG. 6 is a circuit diagram illustrating a circuit configuration of a modification 1 of the third embodiment of the present invention.

FIG. 7 is a circuit diagram illustrating a circuit configuration of a modification 2 of the third embodiment of the present invention.

FIG. 8 is a circuit diagram illustrating a configuration of a fourth embodiment of the present invention.

### EMBODIMENTS

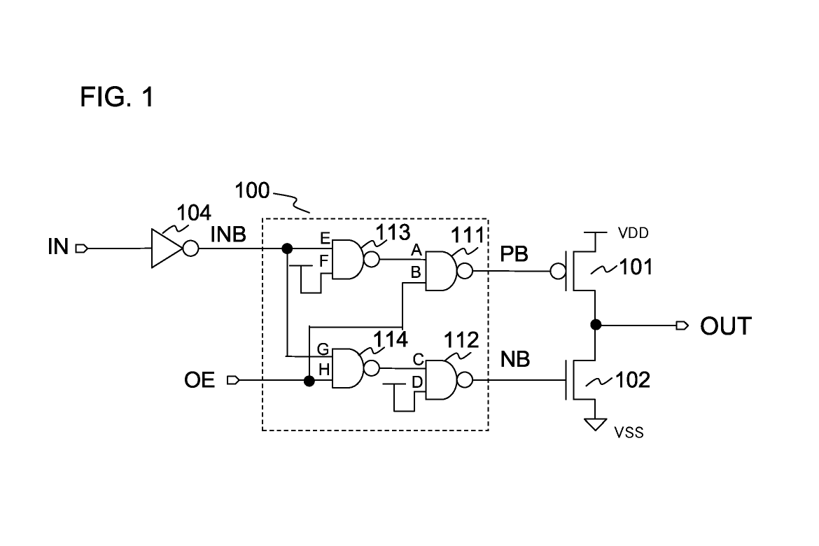

Referring to FIG. 1, a three state buffer according to the first embodiment includes an inverter 104, first to fourth NAND circuits 111-114, a PMOS transistor 101 connected between a first power supply (VDD) and an output terminal OUT, and an NMOS transistor 102 connected between the output terminal OUT and a second power supply (VSS). A signal path to a gate of the PMOS transistor 101, and that to a gate of the NMOS transistor 102 include two stages of NAND circuits (111 and 113) and two stages of NAND circuits (112 and 114), respectively.

The third NAND circuit 113 includes first and second input terminals E and F to receive a signal INB output from the inverter 104 that receives and inverts an input signal IN and the power supply voltage VDD (fixed High level), respectively. The first NAND circuit 111 includes first and second input terminals A and B to receive an output signal of the third NAND circuit 113 and an output enable signal OE, respectively. The fourth NAND circuit 114 includes first and second input terminals G and H to receive the signal INB and the output enable signal OE, respectively. The second NAND circuit 112 includes first and second input terminals C and D to receive an output signal of the fourth NAND circuit 114 and the voltage VDD (fixed High level), respectively. Outputs of the first and second NAND circuits 111 and 112 are connected to the gates nodes PB and NB of the PMOS transistor 101 and the NMOS transistor 102, respectively. A two-input type NAND circuit outputs Low, when both of the two inputs terminals thereof are High, and outputs Low, when at least one of the two inputs terminals thereof is Low. Each of the NAND circuits 112 and 113, whose one input terminal is supplied with a High level, operates as an inverter that inverts a signal at the other input terminal to output the so inverted signal.

The following describes the operation of the three state buffer of FIG. 1. When the output enable signal OE is High and the input signal IN is High, with INB being Low, the output of the NAND circuit 113 is High, and the output of the NAND circuit 111 is Low to render the PMOS transistor 101 conductive (turned on). The output of the NAND circuit 114 is High and hence the output of the NAND circuit 112 is Low to render the NMOS transistor 102 non-conductive (turned off). Thus, the output terminal OUT is High (VDD).

When the output enable signal OE is High and the input signal IN is Low, with INB being High, the output of the NAND circuit 113 is Low and hence the output of the NAND circuit 111 is High to render the PMOS transistor 101 non-conductive. The output of the NAND circuit 114 is Low and hence the output of the NAND circuit 112 is High to render the NMOS transistor 102 conductive. Thus, the output OUT is Low (VSS).

When the output enable signal OE is Low, the output of the NAND circuit 111 is High to render the PMOS transistor 101 non-conductive. The output of the NAND circuit 114 is High and hence the output of the NAND circuit 112 is Low to render the NMOS transistor 102 non-conductive. The PMOS transistor 101 and the NMOS transistor 102 are both non-conductive, and the output OUT is in a high-impedance state.

There is no difference in the circuit configuration between the signal path of the signal INB and that of the output enable signal OE.

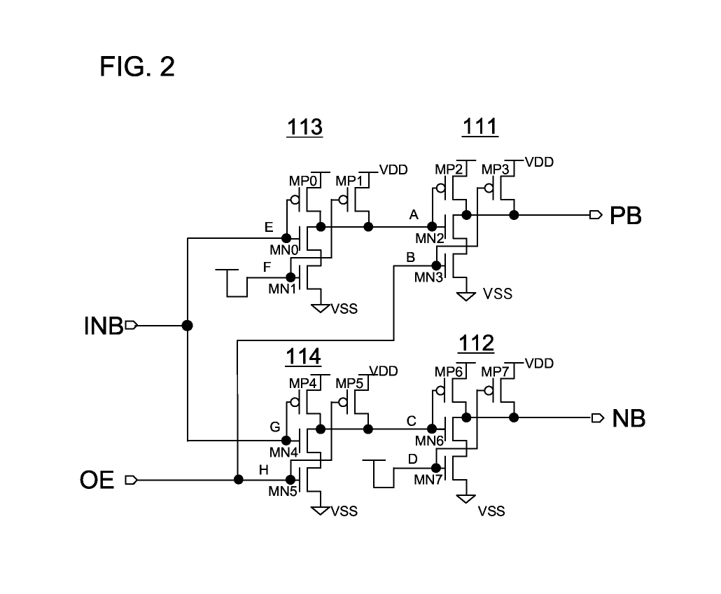

FIG. 2 illustrates a configuration of a circuit block 100 of FIG. 1. The NAND circuit 113 is composed of a well-known standard NAND cell including PMOS transistors MP0 and MP1 and NMOS transistors MN0 and MN1. Sources of the PMOS transistors MP0 and MP1 are connected in common to the power supply VDD. The input signal INB and the power supply voltage VDD are respectively supplied to gate terminals of the PMOS transistors MP0 and MP1 whose drain terminals are coupled together. The NMOS transistors MN0 and MN1 are connected in series between the coupled drains of the PMOS transistors MP0 and MP1 and VSS. Two input signals are supplied to gates of the NMOS transistors MN0 and MN1. Though not limited thereto, the NAND circuits 111-114 in FIG. 2 are each composed of the identical standard NAND cell.

The following describes the operation the circuit of FIG. 2. When the output enable signal OE is High and the inverted signal INB of the input signal IN is High, the PMOS transistor MP0 of the NAND circuit 113 is rendered non-conductive (off) and the NMOS transistor MN0 of the NAND circuit 113 is rendered conductive (on). This brings a node A to a Low level and hence an NMOS transistor MN2 of the NAND circuit 111 is rendered non-conductive and a PMOS transistor MP2 of the NAND circuit 111 is rendered conductive. This brings a node PB to a High level to render the PMOS transistor 101 (FIG. 1) non-conductive (turned off). PMOS transistors MP4 and MP5 of the NAND circuit 111 are rendered non-conductive and an NMOS transistor MN4 of the NAND circuit 114 is rendered conductive to bring a node C to a Low level. Hence, an NMOS transistor MN6 of the NAND circuit 112 is rendered non-conductive and a PMOS transistor MP6 of the NAND circuit 112 is rendered conductive. This brings a node NB to a High level to render the NMOS transistor 102 (FIG. 1) conductive. Thus, the output terminal OUT is Low.

When the output enable signal OE is High and the signal INB of the input signal IN is Low, the NMOS transistor MN0 of the NAND circuit 113 is rendered non-conductive and the PMOS transistor MP0 of the NAND circuit 113 is rendered conductive to bring the node A to a High level. Hence, PMOS transistors MP2 and MP3 are bob non-conductive and an NMOS transistor MN2 of the NAND circuit 111 conductive. This brings the node PB to a Low level to render the PMOS transistor 101 (FIG. 1) conductive. An NMOS transistor MN4 of the NAND circuit 114 is rendered non-conductive and a PMOS transistor MP4 of the NAND circuit 114 is rendered conductive to bring the node C to High. Hence, a PMOS transistor MP6 of the NAND circuit 112 is rendered non-conductive and an NMOS transistor MN6 of the NAND circuit 112 is rendered conductive. This brings the node NB to a Low level to render the NMOS transistor 102 (FIG. 1) non-conductive. Thus, the output OUT is High.

When the output enable signal OE is Low, an NMOS transistor MN3 of the NAND circuit 111 is rendered non-conductive and a PMOS transistor MP3 of the NAND circuit 111 is rendered conductive. This brings the node PB to a High level to render PMOS transistor 101 (FIG. 1) non-conductive. An NMOS transistor MN5 of the NAND circuit 114 is rendered non-conductive and a PMOS transistor MP5 of the NAND circuit 114 is rendered conductive to bring the node C to a High level. Hence, the PMOS transistor MP6 of the NAND circuit 112 is rendered non-conductive and the NMOS transistor MN6 of the NAND circuit 112 is rendered conductive. This brings the node NB to a Low level to render the NMOS transistor 102 (FIG. 1) non-conductive. Since PMOS transistor 101 and the NMOS transistor 102 are both non-conductive, the output OUT (FIG. 1) is in a high-impedance state.

With regard to both the signal path to the gate terminal of the PMOS transistor 101 and the signal path to the gate terminal of the NMOS transistor 102, the junction capacitance, as seen from the drain node of the transistor, are equivalent to that of two parallel PMOS transistors and one NMOS transistor for both of the first stage NAND circuits 113 and 114 and the second stage NAND circuits 111 and 112.

It is seen from above that the signal path to the gate terminal of the PMOS transistor 101 and that to the gate terminal of the NMOS transistor 102 are via the identical circuit configurations, thus yielding high precision access characteristics free of differences in skew or jitter.

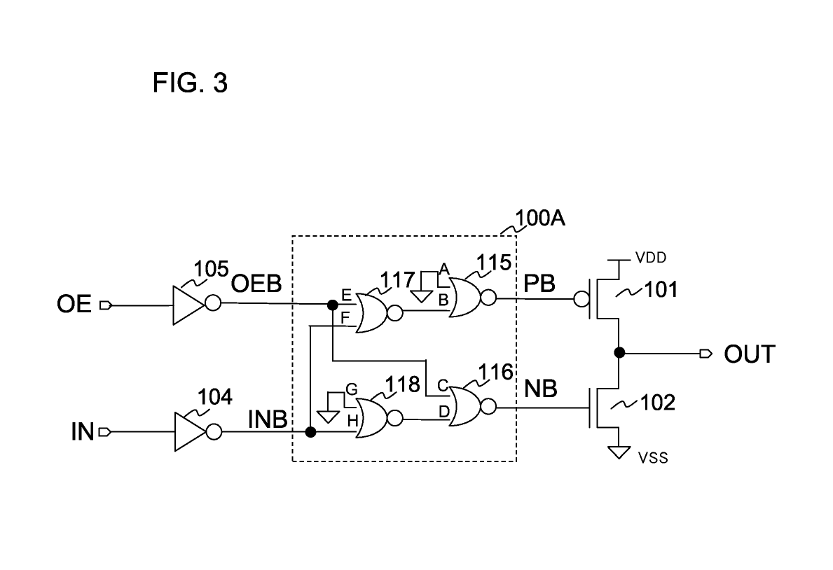

Referring to FIG. 3, a three state buffer according to the second embodiment includes inverters 104 and 105, first to fourth NOR circuits 115-118, a PMOS transistor 101 and an NMOS transistor 102. In the second embodiment, both of the signal path to the gate of the PMOS transistor 101 and the signal path to the gate of the NMOS transistor 102 are composed of two stages of NOR circuits. The third NOR circuit 117 includes first and second input terminals F and E to receive signals INB and OEB, respectively. INB is a signal output of the inverter 104 that receives and inverts an input signal IN. OEB is a signal of the inverter 105 that receives and inverts an output enable signal OE. The first NOR circuit 115 includes first and second input terminals A and B to receive the voltage VSS (fixed Low level) and an output signal of the NOR circuit 117, respectively. The fourth NOR circuit 118 includes first and second input terminals G and H to receive the voltage VSS (fixed Low level) and the signal INB, respectively. The second NOR circuit 116 includes first and second input terminals C and D to receive the signal OEB and an output signal of the fourth NOR circuit 118, respectively. Outputs of the first and second NOR circuits 115 and 116 are coupled to the gate of the PMOS transistor 101 and the gate of the NMOS transistor 102, respectively. A two-input type NOR circuit outputs High, when both of the two input terminals thereof are Low, and outputs Low, when at least one of the two input terminals thereof is High. Each of the two-input type NOR circuits 115 and 118, whose one input terminal is supplied with a Low level, operates an inverter that invert the signal supplied at the other input terminal to output the resulting inverted signal. As shown in FIG. 3, there is no difference between the circuit configuration for the signal INB and that for the signal OEB.

The following describes the operation of the circuit of FIG. 3. When the output enable signal OE is High, and the input signal IN is High, with INB being Low, the output of the NOR circuit 117 is High, and hence the output of the NOR circuit 115 is Low to render the PMOS transistor 101 conductive. The output of the NOR circuit 118 is High and hence the output of the NOR circuit 116 is Low to render the NMOS transistor 102 non-conductive. Thus, the output OUT is High (VDD).

When the output enable signal OE is High, and the input signal IN is Low, with INB being High, the output of the NOR circuit 117 is Low and hence an output of the NOR circuit 115 is High to render the PMOS transistor 101 non-conductive. An output of the NOR circuit 118 is Low and hence an output of the NOR circuit 116 is High to render the NMOS transistor 102 conductive. Thus, the output OUT is Low (VSS).

When the output enable signal OE is Low, the signal OEB is High and hence the output of the NOR circuit 116 is Low to render the NMOS transistor 102 non-conductive. The output of the NOR circuit 117 is Low and hence the output of the NOR circuit 115 is High to render the PMOS transistor 101 non-conductive. Thus, the output OUT is in a high-impedance state.

On each of signal paths connecting to the gate terminals of the PMOS transistor 101 and the NMOS transistor 102, there are provided two-stage of NAND gates in the first embodiment, while there are provided two-stage of NOR gates in the second embodiment. It is noted that any suitable logic gates, such as composite gates, may also be used with comparable beneficent effects, provided that circuits arranged respectively on the signal path connecting to the gate terminal of the PMOS transistor 101 and on the signal path connecting to the gate terminal of the NMOS transistor 102 are each composed of two stages of the logic gates of similar sorts.

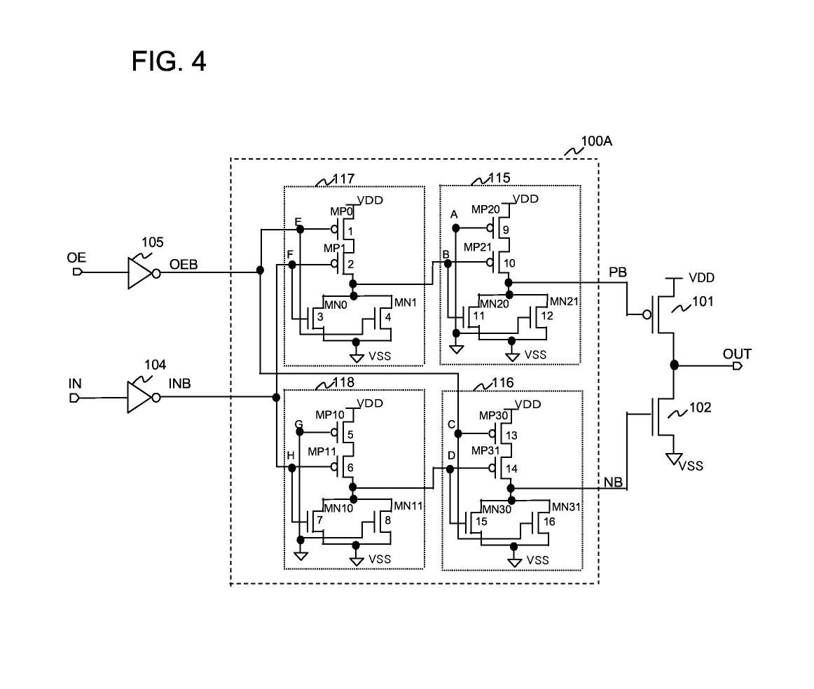

FIG. 4 illustrates a configuration of a circuit block 100A of FIG. 1. The NOR circuit 117 is formed by a well-known standard NOR cell including PMOS transistors MP0 and MP1 and NMOS transistors MN0 and MN1. Sources of the NMOS transistors MN0 and MN1 are connected in common to VSS. Input terminal E and F of the NOR circuit 117 are respectively connected to gate terminals of the NMOS transistors MN0 and MN1 whose drain terminals are coupled together. The PMOS transistors MP0 and MP1 are connected in series between VDD and the coupled drains of the NMOS transistors MN0 and MN1. The input terminals E and F are connected to the gates of the PMOS transistors MP0 and MP1. Though not limited thereto, the NOR circuits 111-114 in FIG. 4 are each composed of the identical standard NAND cell.

The following describes the operation the circuit of FIG. 4. When the output enable signal OE is High, with OEB being Low, and INB is High, the PMOS transistor MP1 of the NOR circuit 117 is rendered non-conductive and the NMOS transistor MN0 of the NOR circuit 117 is rendered conductive to bring a node B to a Low level. Hence a PMOS transistor MP21 of the NOR circuit 115 is rendered conductive. This brings the node PB to a High level to render the PMOS transistor 101 non-conductive. A PMOS transistor MP11 of the NOR circuit 118 is rendered non-conductive and an NMOS transistor MN10 of the NOR circuit 118 is rendered conductive to bring a node D to a Low level. Hence, a PMOS transistor MP31 of the NOR circuit 116 is rendered conductive. A PMOS transistor MP30 of the NOR circuit 116 with a gate terminal supplied with the OEB which is Low, is conductive. This brings the node NB to a Low level to render the NMOS transistor 102 conductive. Thus, the output terminal OUT is Low.

When OEB is Low and the signal INB is Low, the PMOS transistors MP0 and MP1 of the NOR circuit 117 are rendered conductive to bring the node B to a High level. Hence, an NMOS transistor MN20 of the NOR circuit 115 is rendered conductive and a PMOS transistor MP21 of the NOR circuit 115 is rendered non-conductive. This brings the node PB to a Low level to render the PMOS transistor 101 conductive. A PMOS transistor MP11 of the NAND circuit 118 is rendered conductive and an NMOS transistor MN10 of the NOR circuit 118 is rendered non-conductive. This brings the node D to a High level to render an NMOS transistor MN30 of the NOR circuit 116 conductive. This brings the node NB to a Low level to render the NMOS transistor 102 non-conductive. Thus, the output OUT is High.

When the output enable signal OE is Low, with OEB being High, a PMOS transistor MN30 of the NOR circuit 116 is rendered non-conductive and an NMOS transistor MN31 of the NOR circuit 116 is rendered conductive. This brings the node NB to a Low level to render the NMOS transistor 102 non-conductive. A PMOS transistor MP0 of the NOR circuit 117 is rendered non-conductive and an NMOS transistor MN1 of the NOR circuit 117 is rendered conductive to bring the node B to Low. An NMOS transistor of the NOR circuit 115 is rendered non-conductive and the PMOS transistor MP21 is rendered conductive. This brings the node PB to a High level to render the PMOS transistor 101 non-conductive. Thus, the output OUT is in a high-impedance state.

With regard to both the signal path to the gate terminal of the PMOS transistor 101 and the signal path to the gate terminal of the NMOS transistor 102, the junction capacitance, as seen from the drain node of the transistor, are equivalent to that of two parallel NMOS transistors and one PMOS transistor for each of the first stage NOR circuits 117 and 115 and for each of the second stage NOR circuits 118 and 116.

It is seen from above that the signal path to the gate terminal of the PMOS transistor 101 and that to the gate terminal of the NMOS transistor 102 are via the MOS transistors of the same configuration, thus yielding high precision access characteristics free of differences in skew or jitter.

In the above described first and second embodiments, the circuits provided on the signal paths connecting to the gate terminals of the PMOS transistor 101 and the NMOS transistor 102 are formed by the two-stage circuits composed by the same logic gates. However, the present invention is not limited to such configuration, as will be set out in connection with the following exemplary embodiment 3 and so on.

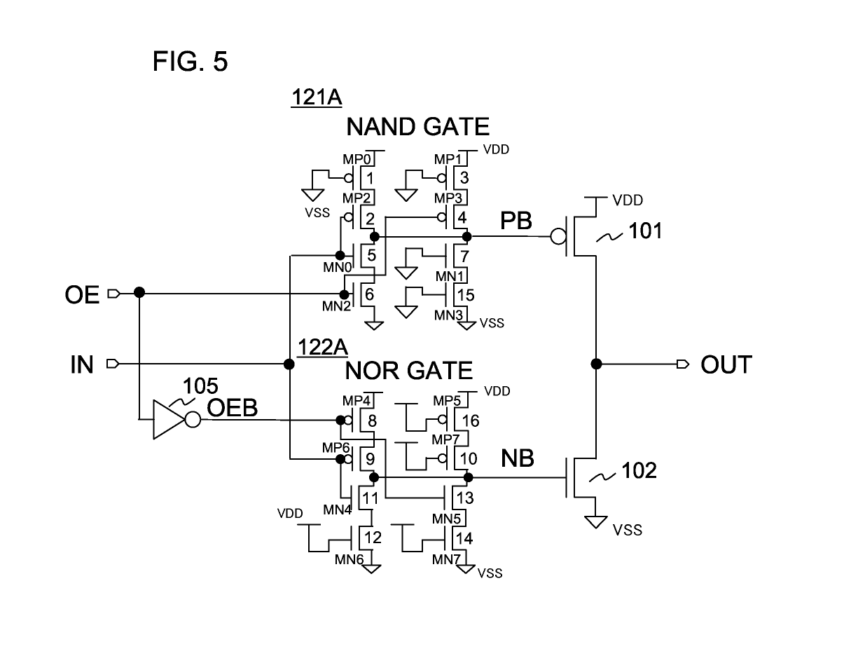

Referring to FIG. 5, a three state buffer according to the third embodiment, includes an inverter 105 that receives the output enable signal OE to output a signal OEB which is an inverted version of OE, a NAND gate 121A, a NOR gate 122A, a PMOS transistor 101 and an NMOS transistor 102. The NAND gate 121A and the NOR gate 122A are of the same configuration to eliminate the difference between the configuration of the input to the gate of the PMOS transistor 101 and that to the gate of the NMOS transistor 102.

The NAND gate 121A includes:

a first PMOS transistor (1:MP0) and a second PMOS transistor (2: MP2) connected in series between the power supply VDD and a first node (PB) and having gate terminals connected respectively to VSS and to an input terminal IN,

a third PMOS transistor (3:MP1) and a fourth P channel MOS transistor (4:MP3) connected in series between VDD and the first node (PB) and having gate terminals connected respectively to VSS and OE.

a fifth N channel MOS transistor (5:MN0) and a sixth N channel MOS transistor (6:MN2) connected in series between the first node (PB) and VSS and having gate terminals respectively connected to IN and to OE, and

a seventh N channel MOS transistor (7:MN1) and 15th N channel MOS transistor (15:MN3) connected in series between the first node (PB) and VSS and having gate terminals both connected to VSS.

A NOR gate 122A includes:

an eighth P channel MOS transistor (8:MP4) and a ninth P channel MOS transistor (9:MP6) connected in series between VDD and the second node (NB) and having gate terminals respectively connected to OEB and IN,

a 16th P channel MOS transistor (16:MP5) and a tenth P channel MOS transistor (10:MP7) connected in series between VDD and the second node (NB) and having gate terminals both connected to VDD,

an eleventh N channel MOS transistor (11:MN4) and a twelfth N channel MOS transistor (12:MN6) connected in series between the second node (NB) and VSS and having gate terminals respectively connected to IN and to VDD,

a 13th N channel MOS transistor (13:MN5) and a 14th NMOS transistor (14:MN7) connected in series between the second node (NB) and VSS and having gate terminals respectively connected to OEB and to VDD. In the above notation, 1:MP0 denotes that the PMOS transistor MP0 has a serial number 1 and 2:MP2 denotes that PMOS transistor MP2 has a serial number 2.

In the NAND gate 121A, when the output enable signal OE is High and the input signal IN is High, the NMOS transistor MN0 is rendered conductive and the PMOS transistors MP2 and MP3 are rendered non-conductive. This sets PB to Low to render the PMOS transistor 101 conductive. In the NOR gate 122A, the PMOS transistor MP4 is rendered conductive (turned on), the PMOS transistor MP6 is rendered non-conductive (turned off) and the NMOS transistor MN4 is rendered conductive (turned on). Thus, NB is Low, so that the NMOS transistor 102 is rendered non-conductive and hence the output OUT is High.

When the output enable signal OE is High and the input signal IN is Low, the PMOS transistor MP2 is rendered conductive (turned on), and the NMOS transistor MN0 is rendered non-conductive (turned off) in the NAND gate 121A. This sets PB to High to turn off the PMOS transistor 102. The PMOS transistor MP4 is rendered conductive (turned on), the PMOS transistor MP6 is rendered conductive (turned on) and the NMOS transistor MN4 is rendered non-conductive (turned off) in the NOR gate 122A. Thus, the node NB is High, so that the NMOS transistor 102 is rendered conductive (turned on), and hence the output OUT is High.

In the NAND gate 121A, when the output enable signal OE is Low, the PMOS transistor MP3 is rendered conductive (turned on). This sets the PB to High to render the PMOS transistor 101 conductive. In the NOR gate 122A, the NMOS transistor MN5 is rendered conductive (turned on) to set the NB to Low. Hence, the NMOS transistor 102 is rendered non-conductive (turned off) so that the output Out is set in a high-impedance state.

The junction capacitances of both the signal path to the gate terminal of the PMOS transistor 101 and the signal path to the gate terminal of the NMOS transistor 102, as seen from the drain, are equivalent to those of two parallel PMOS transistors and two parallel NMOS transistors. The layout may be made the same. Hence, there is produced no difference in parasitic loads.

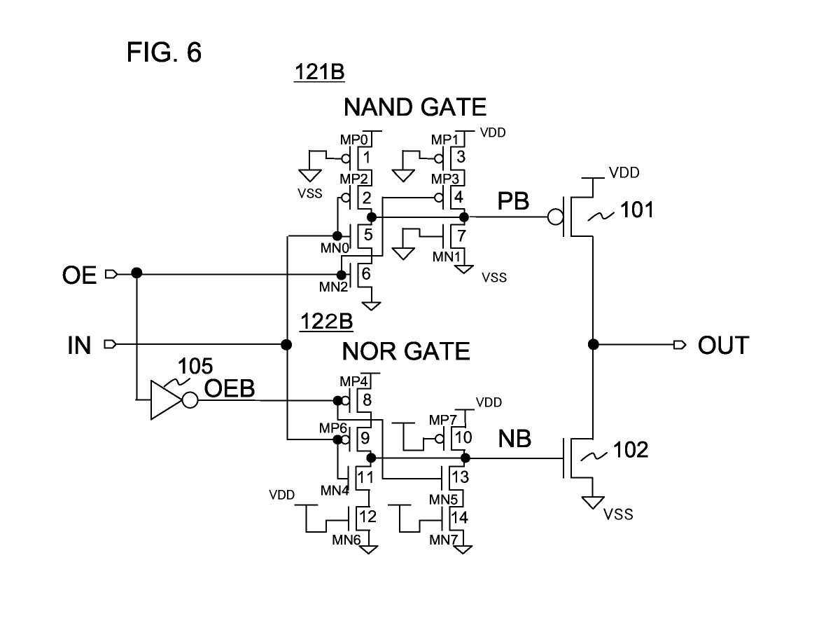

Referring to FIG. 6, in the modification example 1 of the third embodiment of FIG. 5, neither the NMOS transistor MN3 (fifth transistor) nor the PMOS transistor MP5 (16th transistor) is needed, as shown in FIG. 6. Both the NMOS transistor MN3 and the PMOS transistor MP5 in FIG. 5 are eliminated and, in the NAND gate 121B, the source and the drain of the NMOS transistor MN1 (seventh MOS transistor) are connected to PB and to VSS. In the NOR gate 122B, the source and the drain of the PMOS transistor MP7 (tenth MOS transistor) are connected to the first power supply VDD and to NB.

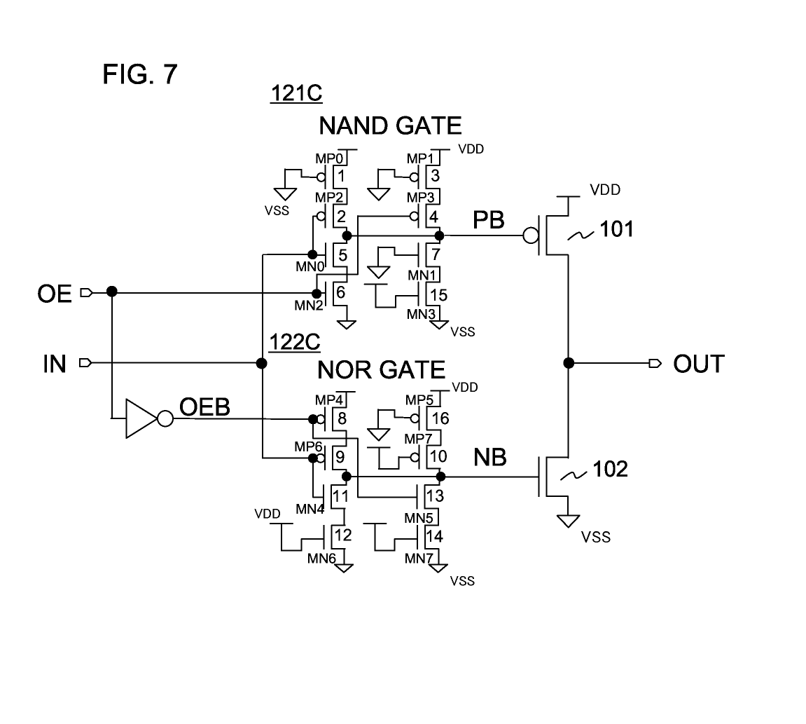

Referring to FIG. 7, in the modification example 2 of the third embodiment, the gate terminal of the NMOS transistor MN3 in FIG. 5 is connected to VDD, and the gate terminal of the PMOS transistor MP5 is connected to the second power supply VSS.

When the output enable signal OE is High, the cascode-connected PMOS transistors MP1 and MP3 are respectively in on and off state in the NAND gate 121C having an output connected to the gate terminal of the PMOS transistor 101, and the cascade-connected PMOS transistors MP5 and MP7 are respectively in on and off states in the NOR gate 122C having an output connected to the gate terminal of the NMOS transistor 102. The two sets of cascade-connected PMOS transistors in the NAND gate 121C and the NOR gate 122C are thus equivalent to each other.

When the output enable signal OE is High, in the NOR gate 122C connected to the gate terminal of the NMOS transistor 102, the cascode-connected NMOS transistors MN5 and MN7 are in on and off states, respectively. On the other hand, in the NAND gate 121C connected to the gate terminal of the PMOS transistor 101, the cascode-connected NMOS transistors MN1 and MN3 are in on and off states, respectively. Hence, two sets of cascode-connected NMOS transistors in the NAND gate 121C and the NOR gate 122C are thus equivalent to each other. Thus, a parasitic load as seen from the first node (PB) is of the same configuration as that seen from the second node (NB).

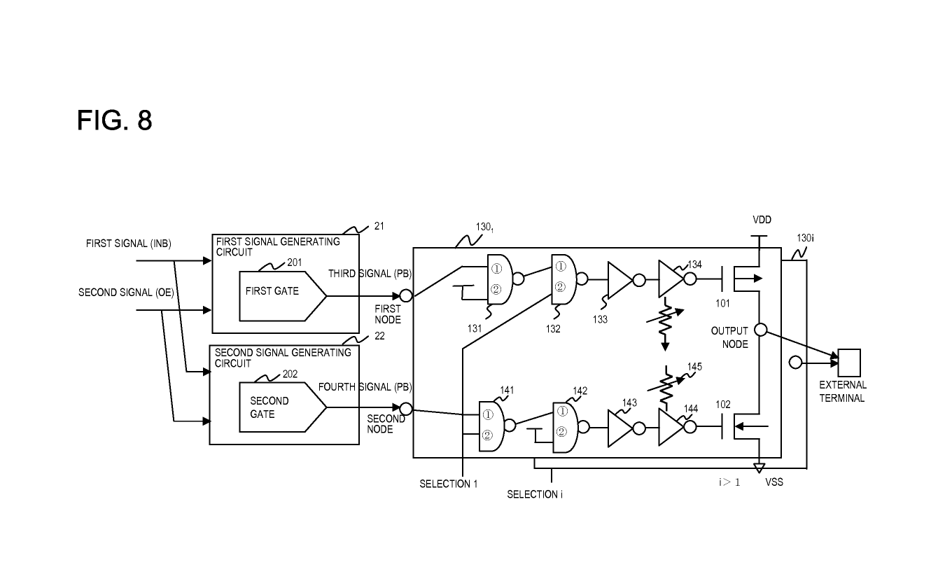

Referring to FIG. 8, in the forth embodiment, a first signal generating circuit 21 and a second signal generating circuit 22, each having a configuration shown in FIG. 1, are used to compose a slew rate control circuit. In the configuration of FIG. 8, the resistance value is varied to adjust the slew rate. An i-number of slew rate circuits 130, where i≧2, are provided to control the current that drives an external terminal (data terminal) to outside of the semiconductor device. Both a third signal PB and a fourth signal NB are entered to the slew rate circuit 130. Specifically, the third signal PB is coupled to a PMOS transistor 101 via NAND circuits 131 and 132, an inverter 133 and an inverter 134 having a variable resistor 135 towards the side of VSS. The fourth signal NB is coupled to an NMOS transistor 102 via NAND circuits 141 and 142, an inverter 143 and an inverter 144 having a variable resistor 145 towards the side of VDD. The drains of the PMOS transistor 101 and the NMOS transistor 102 are connected to an external terminal. When a selection signal 1 is High, the NAND circuits 132 and 141 operate as inverters. The NAND circuits 131 and 132 and the inverters 133 and 134, provided on a signal path connecting to the gate terminal of the PMOS transistor 101, operate as a four-stage inverter. The NAND circuits 141 and 142, and the inverters 143 and 144, provided on a signal path connecting to the gate terminal of the PMOS transistor 102, also operate as four-stages of inverters. When the selection signal 1 is set to Low, the gate terminal of the PMOS transistor 101 is High, and the gate terminal of the NMOS transistor 102 is Low, so that both the PMOS transistor 101 and the NMOS transistor 102 are rendered non-conductive (turned off). When one or all of the selection signals 1 to i is made High, one or all of the i-number slew rate circuits 130 to 130i is selected. The configuration of FIG. 8 may be used for impedance adjustment by ZQ calibration of a DDR (Double Data Rate) SDRAM (Synchronous Dynamic Random Access Memory). As for the ZQ calibration, reference may be had to, for example, the JESD79-3 DDR3 SDRAM section 5.5 of the specification of JEDEC (Joint Electron Device Engineering Council).

The technical concept of the present Application may be applied to a semiconductor device having a signal transmitting circuit. The circuit format in each circuit block as well as the format of the other control signal generating circuits, disclosed in the drawings, is not limited to the format disclosed in the exemplary embodiments. The technical concept of the semiconductor device of the present invention may be applied to a variety of semiconductor devices. For example, the technical concept of the semiconductor device of the present invention may be applied to such semiconductor devices as a CPU (Central Processing Unit), an MCU (Micro Control Unit), a DSP (Digital Signal Processor), an ASIC (Application Specific Integrated Circuit), an ASSP (Application Specific Standard Product) or memories. The semiconductor devices, to which the present invention is applied, may be in the form of, for example, an SOC (system-on-chip), an MCP (multi-chip package) or POP (package-on-package). The present invention may be applied to any of the semiconductor devices having these product or package forms. It is sufficient for the transistor to be a field-effect transistor (Field Effect Transistor). That is, the present invention may be applied to a variety of FETs, namely a MIS (Metal-Insulator Semiconductor) or a TFT (Thin Film Transistor) besides the MOS (Metal Oxide Semiconductor). Part of the transistors in the device may be bipolar transistors. A PMOS transistor (P channel MOS transistor) and an NMOS transistor (N channel MOS transistor) are representative examples of a transistor of a first conductivity type and a transistor of a second conductivity type, respectively.

It is to be noticed that a wide variety of combination or selections of a variety of elements disclosed, inclusive of the elements of respective claims, elements of exemplary embodiments or elements of the drawings may be attempted within the scope of the claims of the present invention. The present invention may encompass a wide variety of modifications or corrections that may occur to those skilled in the art in accordance with the entire disclosure of the present invention, inclusive of claim and the technical concept of the present invention.

What is claimed is:

1. A device comprising:
a first power line supplied with a first voltage as a first logic level;
a second power line supplied with a second voltage as a second logic level;
first and second input nodes supplied with first and second signals, respectively;
first and second output nodes;
a first gate circuit coupled to the first and second power lines, the first and second input nodes and the first output node, the first gate circuit being configured to respond to an inactive level of the first signal to bring the first output node to a first selected one of the first and second logic levels irrespective of a level of the second signal and respond to an active level of the first signal to drive the first output node to a logic level controlled by the level of the second signal, the first logic circuit comprising first and second transistors that are coupled in series between the first output node and the first power line, the first transistor making response to at least one of the first and second signals to change between a conductive state and a non-conductive state, and the second transistor making no response to any one of the first and second signals to keep a conductive state; and
a second gate circuit coupled to the first and second power lines, the first and second input nodes and the second output node, the second gate circuit being configured to respond to the inactive level of the first signal to bring the second output node to a second selected one of the first and second logic levels irrespective of the level of the second signal and respond to the active level of the first signal to drive the second output node to a logic level that is equal to the logic level of the first output node, the second logic circuit comprising third and fourth transistors that are coupled in series between the second output node and the first power line, each of the third and fourth transistors making response to at least one of the first and second signals to change between a conductive state and a non-conductive state.

2. The device as claimed in claim 1, wherein the first selected one of the first and second logic levels and the second selected one of the first and second logic levels are different from each other.

3. The device as claimed in claim 1, further comprising fifth and sixth transistors coupled in series between the first and second power lines, the fifth transistor including a gate electrically coupled to the first output node to be turned OFF by the first selected one of the first and second logic levels, and the sixth transistor including a gate electrically coupled to the second output node to be turned OFF by the second selected one of the first and second logic levels.

4. The device as claimed in claim 1, wherein the first, second, third and fourth transistors are equal in channel type to one another.

5. The device as claimed in claim 1,
wherein the first gate circuit further comprises fifth and sixth transistors that are coupled in parallel between the first output node and the second power line and include gates coupled to gates of the first and second transistors, respectively, the gates of the first and fifth transistors being supplied with a logical combination signal of the first and second signals, the gates of the second and sixth transistors being coupled to the second power line; and
wherein the second gate circuit further comprises seventh and eighth transistors that are coupled in parallel between the second output node and the second power line and include gates coupled to gates of the third and fourth transistors, respectively, the gates of the third and seventh transistors being supplied with the first signal, and the gates of the fourth and eighth transistors being supplied with an inverted signal of the second signal.

6. The device as claimed in claim 5, wherein each of the first, second, third and fourth transistors is of a first channel type and each of the fifth, sixth, seventh and eighth transistors is of a second channel type.

7. The device as claimed in claim 6, wherein the first gate circuit further comprises a first NAND gate that receives the first and second signals and produces the logical combination signal.

8. The device as claimed in claim 7, wherein the first gate circuit further comprises a second NAND gate that includes a first input end supplied with the second signal and a second input end coupled to the second power line and produces the inverted signal.

9. The device as claimed in claim 6, wherein the first gate circuit further comprises a first NOR gate that receives the first and second signals and produces the logical combination signal.

10. The device as claimed in claim 9, wherein the first gate circuit further comprises a second NOR gate that includes a first input end supplied with the second signal and a second input end coupled to the second power line and produces the inverted signal.

11. The device as claimed in claim 1,
wherein the first includes a gate coupled to the second power line and, the second transistor including a gate supplied with the second signal, the third transistor including a gate supplied with an inverted signal of the first signal, and the fourth transistor including a gate supplied with the second signal;
wherein the first gate circuit further comprises fifth and sixth transistors coupled in series between the first output node and the second power line, the fifth transistor including a gate supplied with the second signal, and the sixth transistor including a gate supplied with the first signal; and
wherein the first gate circuit further comprises seventh and eighth transistors coupled in series between the second output node and the second power line, the seventh transistor including a gate supplied with the inverted signal, and the eighth transistor including a gate coupled to the first power line.

12. The device as claimed in claim 11,
wherein the first gate circuit further comprises ninth and tenth transistors coupled in series between the first output node and the first power line, the ninth transistor including a gate supplied with the first signal, and the tenth transistor including a gate coupled to the second power line; and
wherein the second gate circuit further comprises eleventh and twelfth transistors coupled in series between the second output node and the second power line, the eleventh transistor including a gate supplied with the inverted signal, and the twelfth transistor including a gate coupled to the first power line.

13. The device as claimed in claim 12,
wherein the first gate circuit further comprises a thirteenth transistor coupled between the first output node and the second power line and including a agate coupled to the second power line; and
wherein the second gate circuit further comprises a fourteenth transistor coupled between the second output node and the first power line and including a gate coupled to the first power line.

14. The device as claimed in claim 13,
wherein the first gate circuit further comprises a fifteenth transistor coupled in series with the thirteenth transistor between the first output node and the second power line and including a gate coupled to the second power line; and
wherein the second gate circuit further comprises a sixteenth transistor coupled in series with the fourteenth transistor between the second output node and the first power line and including a gate coupled to the first power line.

15. The device as claimed in claim 13,
wherein the first gate circuit further comprises a fifteenth transistor coupled in series with the thirteenth transistor between the first output node and the second power line and including a gate coupled to the first power line; and
wherein the second gate circuit further comprises a sixteenth transistor coupled in series with the fourteenth transistor between the second output node and the first power line and including a gate coupled to the second power line.

16. The device as claimed in claim 12, wherein each of the first, second, third, fourth, ninth, tenth, eleventh and twelfth transistors is of a first channel type and each of the fifth, sixth, seventh and eighth transistors is of a second channel type.

17. The device as claimed in claim 8, further comprising ninth and tenth transistors coupled in series between the first and second power lines, the ninth transistor including a gate coupled to the first output node, and the tenth transistor including a gate coupled to the second output node.

18. The device as claimed in claim 10, further comprising ninth and tenth transistors coupled in series between the first and second power lines, the ninth transistor including a gate coupled to the first output node, and the tenth transistor including a gate coupled to the second output node.

19. The device as claimed in claim 12, further comprising thirteenth and fourteenth transistors coupled in series between the first and second power lines, the thirteenth transistor including a gate coupled to the first output node, and the fourteenth transistor including a gate coupled to the second output node.
